(19) United States
(12) Patent Application Publication
(10) Pub. No.: US 2014/0034367 A1
(43) Pub. Date: Feb. 6, 2014

(54) EPOXY RESIN COMPOSITION FOR PRITNED CIRCUIT BOARD, INSULATING FILM, PREPREG, AND MULTILAYER PRINTED CIRCUIT BOARD

(71) Applicant: SAMSUNG ELECTRO-MECHANICS CO., LTD., Suwon (KR)

(72) Inventors: Jeong Kyu Lee, Suwon (KR); Seong Hyun Yoo, Suwon (KR); Hyun Jun Lee, Suwon (KR); Jin Seok Moon, Suwon (KR); Keun Yong Lee, Suwon (KR)

(73) Assignee: SAMSUNG ELECTRO-MECHANICS CO., LTD., Suwon (KR)

(21) Appl. No.: 13/893,223

(22) Filed: May 13, 2013

(30) Foreign Application Priority Data
Jul. 31, 2012 (KR) 10-2012-0083939

(51) Int. Cl. H05K 1/03

(52) U.S. Cl. CPC H05K 1/0373; H05K 1/0353
USPC 174/255; 525/438; 523/466; 523/433; 523/435

(57) ABSTRACT

Disclosed herein are an epoxy resin composition, an insulating film using the same, and a multilayer printed circuit board; more particularly, an epoxy resin composition including a liquid crystal capable of lowering the coefficient of thermal expansion, improving chemical resistance, and increasing the glass transition temperature, an insulating film or prepreg manufactured by using the epoxy resin composition, and a multilayer printed circuit board including the insulating film or prepreg.

### CROSS REFERENCE TO RELATED APPLICATION

This application claims the benefit of Korean Patent Application No. 10-2012-0083939, filed on Jul. 31, 2012, entitled “Epoxy Resin Composition for Printed Circuit Board, Insulating Film, Prepreg and Multilayer Printed Circuit Board”, which is hereby incorporated by reference in its entirety into this application.

### BACKGROUND OF THE INVENTION

1. Technical Field

The present invention relates to an epoxy resin composition for a printed circuit board, an insulating film, a prepreg, and a multilayer printed circuit board.

2. Description of the Related Art

With the development of electronic devices and request for complicated functions, a printed circuit board has continuously been requested to have a low weight, a thin thickness, and a small size day by day. In order to satisfy these requests, wirings of the printed circuit board becomes more complex, further densified, and higher functioned. In addition, in the printed circuit board, a buildup layer is multilayered, and thus miniature and high densification of wirings are requested. These electrical, thermal, and mechanical characteristics requested for the printed circuit board act as more important factors.

The printed circuit board is mainly composed of copper for circuit wirings and polymer for interlayer insulation. As compared with copper, the polymer constituting an insulating layer requests several characteristics such as coefficient of thermal expansion, glass transition temperature, thickness uniformity, and the like. Particularly, the insulating layer needs to be formed to have a smaller thickness.

As the circuit board is thinner, the board per se has lower rigidity, and thus, may be defective since it is bent at the time of mounting parts at a high temperature. For this reason, thermal expansion characteristics and heat resistance of a thermo-hardening polymer resin are important factors, and the structure of the polymer, the network among chains of the polymer resin constituting the board composition, and hardening density closely affect them at the time of thermal hardening.

Patent Document 1 discloses an epoxy resin composition containing a liquid crystal oligomer. However, the network among liquid crystal oligomer, epoxy resin, and hardener is not sufficiently formed, and thus, does not sufficiently lower the coefficient of thermal expansion to a level appropriate for the printed circuit board and does not sufficiently raise the glass transition temperature.

Patent Document 1 Korean Patent Laid-Open Publication No. 2011-0108198

### SUMMARY OF THE INVENTION

Therefore, the present inventors obtained an insulating film having improved coefficient of thermal expansion, chemical resistance, and glass transition temperature, by mixing a liquid crystal oligomer having a special structure, an epoxy resin having a special structure, a hardener, and an inorganic filler, and based on this, completed the present invention.

The present invention has been made in an effort to provide an epoxy resin composition having a low coefficient of thermal expansion and an improved glass transition temperature.

The present invention has been made in an effort to provide an insulating film having a low coefficient of thermal expansion and an improved glass transition temperature, which was manufactured from the epoxy resin composition.

The present invention also has been made in an effort to provide a multilayer printed circuit board having the insulating film.

According to one preferred embodiment of the present invention, there is provided an epoxy resin composition, including: a liquid crystal oligomer (A) represented by Chemical Formula 1 below; an epoxy resin (B) represented by Chemical Formula 2 below; and a hardener (C).

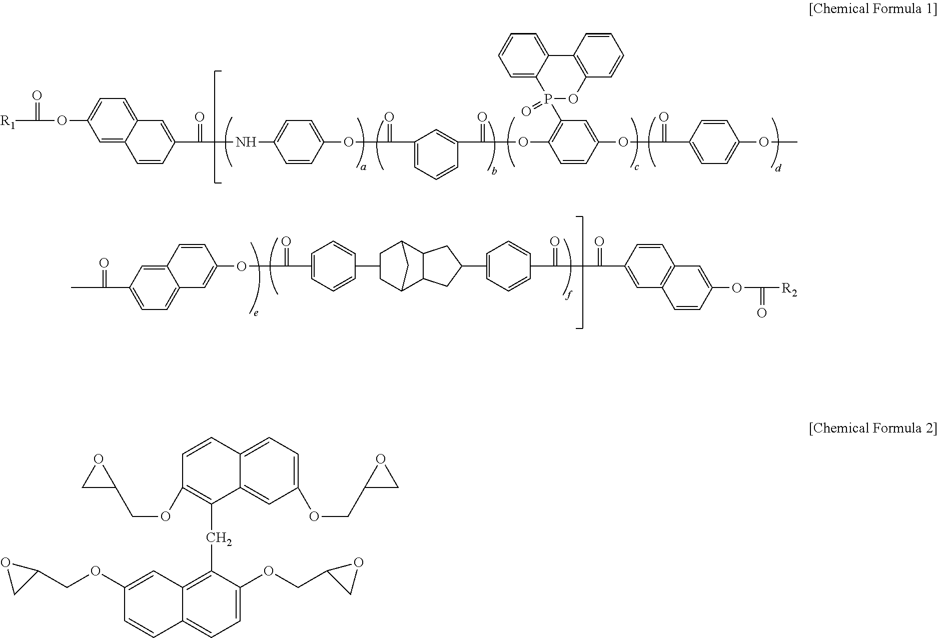

(In Chemical Formula 1, a is an integer of 13 to 26; b is an integer of 13 to 26; c is an integer of 9 to 21; d is an integer of 10 to 30; e is an integer of 10 to 30; and f is an integer of 13 to 17; and R₁ and R₂ are identical or different and each are independently C1˜C20 alkyl)

According to another preferred embodiment of the present invention, there is provided an epoxy resin composition, including: a liquid crystal oligomer (A) represented by Chemical Formula 1 below; an epoxy resin (B) represented by Chemical Formula 2 below; a hardener (C); and an inorganic filler (D).

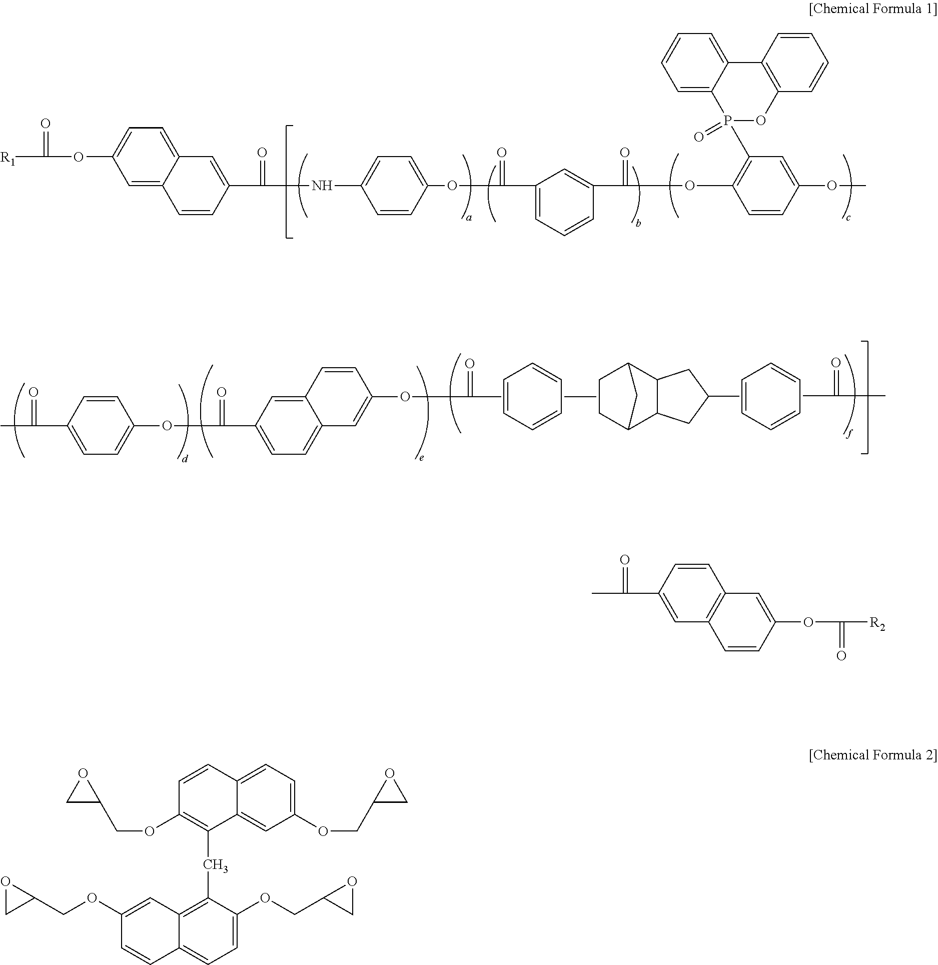

(In Chemical Formula 1, a is an integer of 13 to 26; b is an integer of 13 to 26; c is an integer of 9 to 21; d is an integer of 10 to 30; e is an integer of 10 to 30; and f is an integer of 13 to 17; and R₁ and R₂ are identical or different and each are independently C1˜C20 alkyl)

The epoxy resin composition may include 35 to 65 wt % of the liquid crystal oligomer (A), 35 to 65 wt % of the epoxy resin (B), and 0.1 to 1 part by weight of the hardener (C) based on 100 parts by weight of the liquid crystal oligomer (A) and the epoxy resin (B).

The epoxy resin composition may include 35 to 65 wt % of the liquid crystal oligomer (A), 35 to 65 wt % of the epoxy resin (B), 0.1 to 1 part by weight of the hardener (C) based on 100 parts by weight of the liquid crystal oligomer (A) and the epoxy resin (B), and 100 to 160 parts by weight of the inorganic filler (D) based on 100 parts by weight of the liquid crystal oligomer (A) and the epoxy resin (B).

The liquid crystal oligomer (A) may have a number average molecular weight of 2,500 to 6,500.

The epoxy resin composition may further include another epoxy resin, the epoxy resin being at least one selected from a naphthalene based epoxy resin, a bisphenol A epoxy resin, a phenol novolac epoxy resin, a cresole novolac epoxy resin, a rubber modified epoxy resin, and a phosphorous-based epoxy resin.

The hardener (C) may be at least one selected from an amide based hardener, a polyamine based hardener, an acid anhydride hardener, a phenol novolac hardener, a polymercaptan hardener, a tertiary amine hardener, and an imidazole hardener.

The inorganic filler (D) may be at least one selected from the group consisting of silica, alumina, barium sulfate, talc, mud, a mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titan oxide, barium zirconate, and calcium zirconate.

The epoxy resin composition may further include a hardening accelerant (E), the hardening accelerant (E) being at least one selected from 2-methyl imidazole, 2-undecyl imidazol, 2-heptadecyl imidazole, 1,2-dimethyl imidazole, 2-ethyl-4-methyl imidazole, 1,2-dimethyl imidazole, 2-ethyl-4-methyl imidazole, 2-phenyl imidazole, 2-phenyl-4-methyl imidazole, 1-benzyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undencyl imidazolium trimellitate, 1-cyanoethyl-2-phenyl imidazolium trimellitate, 2,4-diamino-6-[2′-methyl imidazolyl-(1′)]-ethyl-s-triazine, 2,4-diamino-6-[2′-undecyl imidazolyl-(1)]-ethyl-s-triazine, 2,4-diamin-6-[2′-ethyl-4′-methyl imidazolyl-(1)]-ethyl-s-triazine, 2,4-diamino-6-[2′-methyl imidazolyl-(1′)]ethyl-s-triazine isocyanuric acid adduct, 2-phenyl imidazole isocyanuric acid adduct, 2-phenyl-4,5-dihydroxymethyl imidazole, 2-phenyl-4-methyl-5-hydroxy methyl imidazole, 2,3-dihydroxy-1H-pyrrolo[1,2-a]benz imidazole, 1-dodecyl-2-methyl-3-benzyl imidazolium chloride, and 2-methyl imidazolin, 2-phenyl imidazolin.

The epoxy resin composition may further include a thermoplastic resin (F), the thermoplastic resin being at least one selected from a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, and a polyester resin.

According to still another preferred embodiment of the present invention, there is provided an insulating film manufactured from the epoxy resin composition as described above.

According to still another preferred embodiment of the present invention, there is provided a prepreg manufactured by impregnating a substrate with the epoxy resin composition as described above.

According to still another preferred embodiment of the present invention, there is provided a multilayer printed circuit board comprising the insulting film as described above.

According to still another preferred embodiment of the present invention, there is provided a multilayer printed circuit board comprising the prepreg as described above.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a general printed circuit board to which an epoxy resin composition according to the present invention is applicable;

FIGS. 2A and 2B are images of insulating films before acid treatment (FIG. 2A) and after acid treatment (FIG. 2B) according to Example 1; and

FIGS. 3A and 3B are images of insulating films before acid treatment (FIG. 3A) and after acid treatment (FIG. 3B) according to Comparative Example 1.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

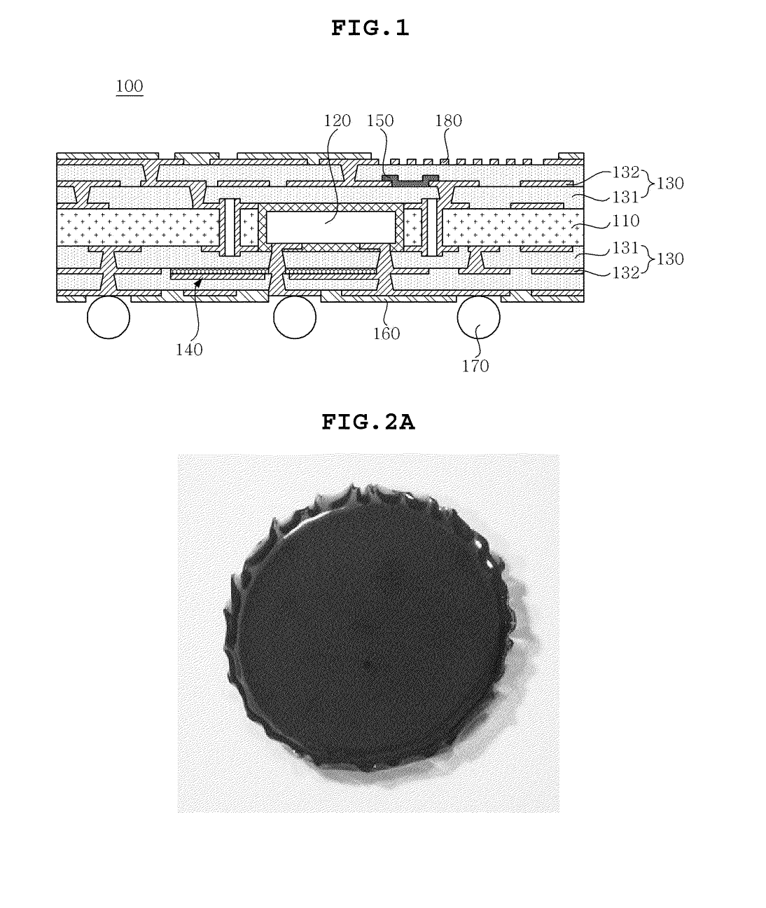

FIG. 1 is a cross-sectional view of a general printed circuit board to which an epoxy resin composition according to the present invention is applicable. Referring to FIG. 1, a printed circuit board 100 may be an embedded substrate having electronic parts therein. Specifically, the printed circuit board 100 may include an insulator or prepreg 110 having a cavity, an electronic part 120 disposed inside the cavity, and a buildup layer 130 disposed on at least one of an upper surface and a lower surface of the insulator or prepreg 110 including the electronic part 120. The buildup layer 130 may include an insulating layer 131 disposed on at least one of the upper surface and the lower surface of the insulator 110 and a circuit layer 132 disposed on the insulating layer 131 and form an interlayer connection.

Here, an example of the electronic component 120 may be an active device such as a semiconductor device. In addition, the printed circuit board 100 may not have only one electronic part 120 therein but further have one or more additive electronic parts, such as a capacitor 140, a resistor element 150, and the like. In the present invention, the type or number of electronic parts is not limited. Here, the insulator or prepreg 110 and the insulating layer 131 may serve to insulate between circuit layers or between electronic parts, and also serve as a structural member for maintaining rigidity of a package.

Here, when wiring density of the printed circuit substrate 100 is increased, the insulator or prepreg 110 and the insulating layer 131 require the low-K characteristics in order to reduce noise between the circuit layers and parasitic capacitance, and the insulator or prepreg 110 and the insulating layer 131 also require the low dielectric loss characteristics in order to increase the insulating characteristics.

As such, at least one of the insulator or prepreg 110 and the insulating layer 131 needs to decrease the dielectric constant, the dielectric loss, and the like, and have the rigidity. In the present invention, in order to secure the rigidity by lowering the coefficient of thermal expansion of the insulating layer and raising the glass transition temperature, the insulating layer may be formed from an epoxy resin composition containing a liquid crystal oligomer (A) represented by Chemical Formula 1; an epoxy resin (B) represented by Chemical Formula 2; and a hardener (C).

In addition, the insulating layer or prepreg may be formed from an epoxy resin composition containing a liquid crystal oligomer (A) represented by Chemical Formula 1; an epoxy resin (B) represented by Chemical Formula 2; a hardener (C); and an inorganic filler (D).

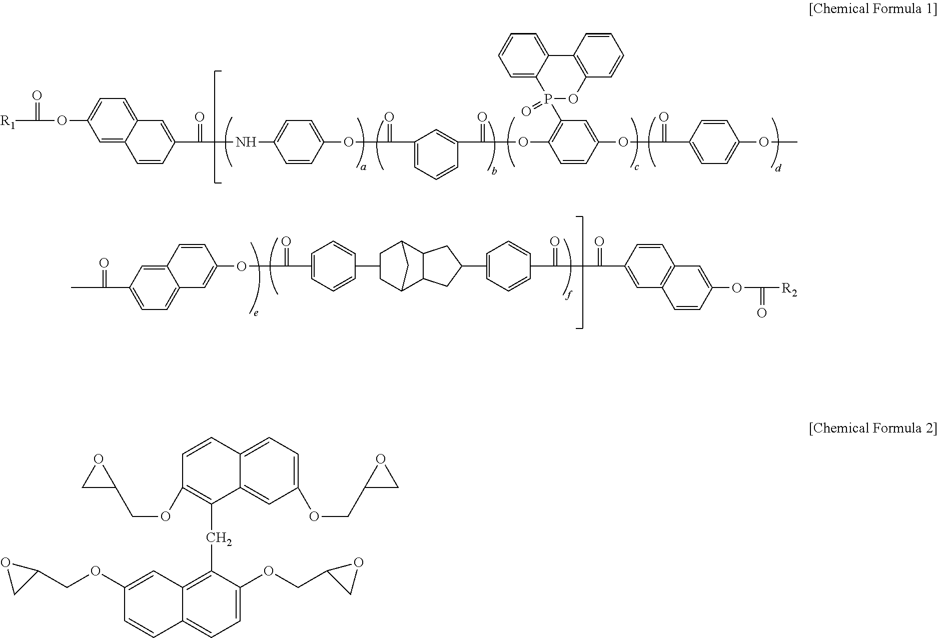

In Chemical Formula 1, a is an integer of 13 to 26; b is an integer of 13 to 26; c is an integer of 9 to 21; d is an integer of 10 to 30; e is an integer of 10 to 30; and f is an integer of 13 to 17; and R₁ and R₂ are identical or different and each are independently C1˜C20 alkyl.

Liquid Crystal Oligomer (A)

The liquid crystal (A) represented by Chemical Formula 1 above may contain ester groups at both ends of a main chain in order to improve the dielectric dissipation factor and the dielectric constant; contain a phosphorous component imparting flame retardancy; and contain a naphthalene group for crystallinity.

The liquid crystal oligomer has a number average molecular weight of, preferably, 2,500 to 6,500 g/mol, and more preferably, 3,000 to 6,000 g/mol. If the number average molecular weight of the liquid crystal oligomer is below 2,500 g/mol, mechanical properties may be deteriorated. If the number average molecular weight thereof is above 6,500 g/mol, solubility may be deteriorated. The use amount of liquid crystal oligomer (A) is preferably 35 to 65 wt %, and more preferably 40 to 60 wt %. If the use amount thereof is below 35 wt %, the reduction in coefficient of thermal expansion and the improvement in glass transition temperature may be slight. If the use amount thereof is above 65 wt %, mechanical properties may be deteriorated.

Epoxy Resin (B)

The epoxy resin composition according to the present invention may contain an epoxy resin (B) of Chemical Formula 2 below in order to improve the handling property of the resin composition as an adhering film after drying.

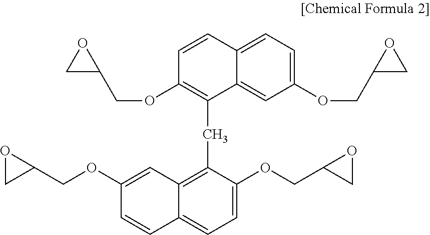 [SMILES: c1cc2ccc(OCC3CO3)c(Cc3c(OCC4CO4)ccc4ccc(OCC5CO5)cc34)c2cc1OCC1CO1]

The naphthalene structured epoxy resin may contain a glycidyl group. The naphthalene structured epoxy resin may be a polycondensate of 1-chloro-2,3-epoxypropane, formaldehyde, and 2,7-naphthalene diol. A hard naphthalene mesogen structure in the composite improves crystallinity of the polymer, to thereby exhibit a low coefficient of thermal expansion and high heat resistance. In addition, four functional groups of naphthalene epoxy react with a hydroxyl group of the liquid crystal oligomer to form hardening density. The use amount of epoxy resin (B) is preferably 35 to 65 wt %, and more preferably 40 to 60 wt %. If the use amount thereof is below 35 wt %, the handling property may be degraded. If the use amount thereof is above 65 wt %, the adding amount of other components is relatively small, and thus, the dielectric dissipation factor, the dielectric constant; and the coefficient of thermal expansion are less improved.

The epoxy resin composition may further include at least one epoxy resin selected from a naphthalene based epoxy resin, a bisphenol A epoxy resin, a phenol novolac epoxy resin, a cresole novolac epoxy resin, a rubber modified epoxy resin, and a phosphorous-based epoxy resin. The epoxy resin composition according to the present invention may further include another epoxy resin additively besides the epoxy resin (B). The epoxy resin means a material that contains, but is not particularly limited to, at least one epoxy group in a molecule thereof, and preferably at least two epoxy groups in a molecule thereof, and more preferably at least four epoxy groups in a molecule thereof. Examples of the epoxy resin may include, but are not particularly limited to, a bisphenol A epoxy resin, a bisphenol F epoxy resin, a bisphenol S epoxy resin, a phenol novolac epoxy resin, an alkylphenol novolac epoxy resin, a biphenyl epoxy resin, an aralkyl epoxy resin, a dicyclopentadiene epoxy resin, a naphthalene epoxy resin, a naphthol epoxy resin, an epoxy resin of a condensate of phenol and aromatic aldehyde having a phenolic hydroxyl group, a biphenylaralkyl epoxy resin, a fluorene epoxy resin, a xanthene epoxy resin, a triglycidyl isocianurate resin, a rubber modified epoxy resin, and a phosphorus based epoxy resin, and preferable are the naphthalene based resin, bisphenol A epoxy resin, phenol novolac epoxy resin, cresol novolac epoxy resin, rubber modified epoxy resin, and phosphorous based epoxy resin. One kind or two or more kinds of epoxy resins may be mixed for use.

Hardener (C)

Meanwhile, as the hardener (C) used in the present invention, any one that can be generally used in order to thermally harden an epoxy resin may be used, but is not particularly limited thereto. Specifically, examples thereof may include: amide based hardeners such as dicyanamide and the like; polyamine based hardeners such as diethylenetriamine, triethylene tetraamine, N-aminoethyl piperazine, diamino diphenyl methane, adipic acid dihydrazide, and the like; acid anhydride hardeners, such as pyrometallic acid anhydride, benzophenone tetracarboxylic acid anhydride, ethylene glycol bis trimetallic acid anhydride, glycerol tris trimetallic anhydride, maleic methyl cyclohexene tetracarboxylic acid anhydride, and the like; phenol novolac type hardeners; polymercaptan hardeners such as trioxane tritylene mercaptan and the like; tertiary amine hardeners such as benzyl dimethyl amine, 2,4,6-tris(dimethyl amino methyl) phenol, and the like; imidazole hardeners such as 2-ethyl-4-methyl imidazole, 2-methyl imidazole, 1-benzyl-2-methyl imidazole, 2-heptadecyl imidazole, 2-undecyl imidazole, 2-phenyl-4-methyl-5-hydroxy-methyl imidazole, 2-phenyl-imidazole, 2-phenyl-4-methyl imidazole, 1-benzyl-2-phenyl-imidazole, 1,2-dimethyl-imidazole, 1-cyanoethyl-2-phenyl imidazole, 2-phenyl-4,5-dihydroxymethyl imidazole, and the like, and one or two or more of hardeners may be used in combination. Particularly, dicyanamide is preferable in view of physical property.

The use amount of hardener (C) is preferably 0.1 to 1 part by weight based on 100 parts by weight of the total of the liquid crystal oligomer (A) and the epoxy resin (B). If the use amount thereof is below 0.1 parts by weight, the hardening rate is decreased. If the use amount thereof is above 1 part by weight, an unreacted hardener remains, which causes to increase the moisture absorption rate of an insulating substrate and/or an insulating layer, and thus, electrical properties tend to be deteriorated.

Inorganic Filler (D)

The epoxy resin composition according to the present invention contains an inorganic filler (D) in order to lower the coefficient of thermal expansion (CTE) of the epoxy resin. The inorganic filler (D) lowers the coefficient of thermal expansion, and the content thereof based on the resin composition is varied depending on characteristics requested in consideration of usage of the epoxy resin composition or the like, but is preferably 100 to 160 parts by weight based on 100 parts by weight of the total of the liquid crystal oligomer (A) and the epoxy resin (B). If the content ratio thereof is below 100 wt %, the dielectric dissipation factor is lowered and the coefficient of thermal expansion is increased. If the content ratio thereof is above 160 parts by weight, the adhering strength tends to be decreased. The content of inorganic filler is more preferably at least 120 parts by weight based on solids of the entire resin composition.

Specific examples of the inorganic filler used in the present invention may include silica, alumina, barium sulfate, talc, mud, a mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titan oxide, barium zirconate, calcium zirconate, and the like, which are used alone or in combination of two or more thereof. Particularly, preferable is silica having a low dielectric dissipation factor.

In addition, if the inorganic filler has an average particle size of 5 μm or larger, it is difficult to form a fine pattern stably when a circuit pattern is formed in a conductor layer. Hence, the average particle size of the inorganic filler is preferably 5 μm or less. In addition, the inorganic filler is preferably surface-treated with a surface treating agent such as a silane coupling agent, in order to improve the moisture resistance. More preferable is silica having a diameter of 0.2 to 2 μm.

Hardening Accelerant (E)

The resin composition of the present invention can also perform efficient hardening by selectively containing a hardening accelerant (E). Examples of the hardening accelerant used in the present invention may include a metal based hardening accelerant, an imidazole based hardening accelerant, an amine based hardening accelerant, and the like, and one or combination of two or more thereof may be added and used in a general amount used in the art.

Examples of the metal based hardening accelerant may include, but are not particularly limited to, an organic metal complex or organic metal salt of a metal, such as, cobalt, copper, zinc, iron, nickel, manganese, tin, or the like. Specific examples of the organic metal complex may include an organic cobalt complex such as cobalt (II) acetylacetonate, cobalt (III) acetylacetonate, and the like, an organic copper complex such as copper (II) acetylacetonate or the like, an organic zinc complex such as zinc (II) acetylacetonate or the like, an organic iron complex such as iron (III) acetylacetonate or the like, an organic nickel complex such as nickel (II) acetylacetonate or the like, and an organic manganese complex such as manganese (II) acetylacetonate or the like. Examples of the organic metal salt may include zinc octylate, tin octylate, zinc naphthenate, cobalt naphthenate, tin stearate, zinc stearate, and the like. As the metal based hardening accelerator, in view of hardening property, preferable are cobalt (II) acetylacetonate, cobalt (III) acetylacetonate, zinc (II) acetylacetonate, zinc naphthenate, and iron (III) acetylacetonate, and more preferable are cobalt (II) acetylacetonate and zinc naphthenate. One kind or two or more kinds of metal based hardening accelerants may be used in combination.

Examples of the imidazole based hardening accelerant may include, but are not particularly limited to, an imidazole compound, such as, 2-methyl imidazole, 2-undecyl imidazol, 2-heptadecyl imidazole, 1,2-dimethyl imidazole, 2-ethyl-4-methyl imidazole, 1,2-dimethyl imidazole, 2-ethyl-4-methyl imidazole, 2-phenyl imidazole, 2-phenyl-4-methyl imidazole, 1-benzyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undencyl imidazolium trimellitate, 1-cyanoethyl-2-phenyl imidazolium trimellitate, 2,4-diamino-6-[2′-methyl imidazolyl-(1′)]-ethyl-s-triazine, 2,4-diamino-6-[2′-undecyl imidazolyl-(1′)]-ethyl-s-triazine, 2,4-diamin-6-[2′-ethyl-4′-methyl imidazolyl-(1′)]-ethyl-s-triazine, 2,4-diamino-6-[2′-methyl imidazolyl-(1′)]-ethyl-s-triazine isocyanuric acid adduct, 2-phenyl imidazole isocyanuric acid adduct, 2-phenyl-4,5-dihydroxymethyl imidazole, 2-phenyl-4-methyl-5-hydroxy methyl imidazole, 2,3-dihydroxy-1H-pyrrolo[1,2-a]benz imidazole, 1-dodecyl-2-methyl-3-benzyl imidazolium chloride, 2-methyl imidazolin, 2-phenyl imidazolin, or the like, and an adduct body of the imidazole compound and an epoxy resin. One kind or two or more kinds of imidazole hardening accelerants may be used in combination.

Examples of the amine based hardening accelerant may include, but are not particularly limited to, an amine compound, for example, trialkyl amine such as trimethylamine, tributylamine, or the like, 4-dimethylaminopyridine, benzyldimethyl amine, 2,4,6-tris(dimethylaminomethyl)phenol, 1,8-diazabicyclo(5,4,0)-undecene (hereinafter, referred to as DBU), or the like. One kind or two or more kinds of amine based hardening accelerants may be used in combination.

Thermoplastic Resin (F)

The resin composition of the present invention may selectively include a thermoplastic resin (F) in order to improve film property thereof or improve mechanical property of the hardened material. Examples of the thermoplastic resin may include a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, a polyester resin, and the like. These thermoplastic resins may be used alone or in mixture of two or more. The average weight molecular weight of the thermoplastic resin is preferably within a range of 5,000 to 200,000. If the average weight molecular weight thereof is below 5,000, effects of improving film formability and mechanical strength are not sufficiently exhibited. If the average weight molecular weight thereof is above 200,000, compatibility with the liquid crystal oligomer and the epoxy resin is not sufficient; the surface unevenness after hardening becomes larger; and high-density fine wirings are difficult to form. The weight molecular weight is measured at a column temperature of 40 C by using LC-9A/RID-6A of Shimadzu Corporation as a measuring apparatus, Shodex K-800P/K-804L/K-804L of Showa Denko Company as a column, and chloroform (CHCl₃) as a mobile phase, and then calculated by using a calibration curve of standard polystyrene.

In the case where a thermoplastic resin (F) is blended with the resin composition of the present invention, the content of thermoplastic resin in the resin composition is, but is not particularly limited to, preferably 0.1 to 10 parts by weight, and more preferably 1 to 5 parts by weight, based on 100 wt % of non-volatile matter in the resin composition. If the content of thermoplastic resin is below 0.1 parts by weight, an effect of improving film formability or mechanical strength is not exhibited. If the content thereof is above 10 parts by weight, molten viscosity may tend to be increased and the surface roughness of an insulating layer after a wet roughening process may tend to be increased.

The insulating resin composition according to the present invention is mixed in the presence of an organic solvent. Examples of the organic solvent, considering solubility and miscibility of the resin and other additives used in the present invention, may include 2-methoxy ethanol, acetone, methyl ethyl ketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethyl formamide, and dimethyl acetamide, but are not particularly limited thereto.

The viscosity of the epoxy resin composition according to the present invention is preferably 1000 to 2000 cps in the case where the inorganic filler is not contained, and preferably 700 to 1500 cps in the case where the inorganic filler is contained, and this viscosity is suitable for manufacturing the insulating film and allows appropriate adhesive property at the normal temperature. The viscosity of the epoxy resin composition may be controlled by varying the content of the solvent. Other non-volatile components excluding the solvent account for 30 to 70 wt % based on the epoxy resin composition. If the viscosity of the epoxy resin composition is out of the above range, it is difficult to form the insulating film, or it is difficult to mold a member even though the insulating film.

Besides, the present invention may further include, as necessary, other known leveling agents and/or flame retardants by those skilled in the art within the technical scope of the present invention.

According to the insulating resin composition of the present invention, a semisolid phase dry film can be prepared by any general method known in the art. For example, a film may be manufactured by using a roll coater, a curtain coater, or the like, and then dried. Then, the film is applied onto a substrate, to thereby be used as an insulating layer (or an insulating film) or prepreg when the multilayer printed circuit board is manufactured in a build-up manner. This insulating film or prepreg has a low coefficient of thermal expansion (CTE) of 50 ppm/° C. or lower.

As such, the prepreg is prepared by impregnating a substrate such as a glass fiber or the like with the epoxy resin composition according to the present invention, followed by hardening, and then a copper foil is laminated thereon, thereby obtaining a copper clad laminate (CCL). In addition, the insulating film manufactured by using the epoxy resin composition of the present invention is laminated on a copper clad laminate (CCL) used as an inner layer at the time of manufacturing the multilayer printed circuit board. For example, the multilayer printed circuit board may be manufactured by laminating the insulating film formed of the insulating resin composition on a patterned inner layer circuit board; hardening it at a temperature of 80 to 110° C. for 20 to 30 minutes; performing a desmear process, and then forming a circuit layer through an electroplating process.

Hereinafter, the present invention will be described in more detail with reference to the following examples and comparative examples, but the scope of the present invention is not limited thereto.

### PREPARATIVE EXAMPLE 1

Preparation of Liquid Crystal Oligomer

4-aminophenol of 218.26 g(2.0 mol), isophthalic acid of 415.33 g(2.5 mol), 4-hydroxybenzoic acid of 276.24 g(2.0 mol), 6-hydroxy-2-naphthoic acid of 282.27 g(1.5 mol), 9,10-dihydroxy-9-oxa-10-phosphaphenanthrene-10-oxide (DOPO) of 648.54 g(2.0 mol), and acetic acid anhydride of 1531.35 g(15.0 mol) were put in 20 L of a glass reactor. The inside of the reactor was sufficiently replaced with nitrogen gas, and then the temperature of the reactor was raised to230° C. under the flow of the nitrogen gas. The nitrogen gas was circulated for 4 hours while the inner temperature of the reactor was maintained at that temperature. 6-Hydroxy-2-naphthoic acid for endcapping of 188.18 g(1.0 mol) was further added, and then acetic acid, which is a reaction byproduct, and unreacted acetic acid anhydride were removed, to thereby prepare a liquid crystal oligomer of Chemical Formula 1 below, having a molecular weight of about 4500.

### EXAMPLE 1

4.4 g of naphthalene structured epoxy (1-chloro-2,3-epoxypropane formaldehyde 2,7-naphthalene dior polycondensate) having an average epoxy equivalent was added to 9.0 g of N,N-dimethylacetamide, and then was stirred and dissolved at room temperature by using a magnetic bar at 300 rpm, thereby preparing a mixture. After that, 6.6 g of the liquid crystal oligomer prepared according to the preparative example 1 was added to the mixture, and then further stirred for 4 hours. 0.044 g of a dicyandiamide hardener was added to the mixture solution, and then further stirred for 2 hours, to thereby prepare a liquid crystal oligomer resin composition. The mixture solution was coated on a copper foil, followed by semi-hardening at 100° C., and then heat-pressed at 230° C. by using a vacuum press, to thereby obtain a heat-hardened film.

### EXAMPLE 2

2.64 g of N,N,N′,N′-tetraglycidyl-4,4′-methylenebisbenzenamine having an average epoxy equivalent of 100 to 120 and 1.76 g of naphthalene structured epoxy (1-chloro-2,3-epoxypropane formaldehyde 2,7-naphthalene dior polycondensate) having an average epoxy equivalent of 160 to 180 were added to 9.0 g of N,N-dimethylacetamide, and then was dissolved and stirred at room temperature by using a magnetic bar at 300 rpm, thereby preparing a mixture. After that, 6.6 g of the liquid crystal oligomer prepared according to the preparative example 1 was added to the mixture, and then further stirred for 4 hours. 0.044 g of a dicyandiamide hardener was added to the mixture liquid, and then further stirred for 2 hours, to thereby prepare a liquid crystal oligomer resin composition. The mixture solution was coated on a copper foil, followed by semi-hardening at 100° C., and then heat-pressed at 230° C. by using a vacuum press, to thereby obtain a heat-hardened film.

### COMPARATIVE EXAMPLE 1

4.4 g of N,N,N′,N′-tetraglycidyl-4,4′-methylenebisbenzenamine having an average epoxy equivalent of 100 to 120 was added to 9.0 g of N,N-dimethylacetamide, and then was stirred and dissolved at mom temperature by using a magnetic bar at 300 rpm, thereby preparing a mixture. After that, 6.6 g of the liquid crystal oligomer prepared according to the preparative example 1 was added to the mixture, and then further stirred for 4 hours. 0.044 g of a dicyandiamide hardener was added to the mixture liquid, and then further stirred for 2 hours, to thereby prepare a liquid crystal oligomer resin composition. The mixture solution was coated on a copper foil, followed by semi-hardening at 100° C., and then heat-pressed at 230° C. by using a vacuum press, to thereby obtain a heat-hardened film.

Construct of Sample for Evaluating Coefficient of Thermal Expansion and Glass Transition Temperature

Each resin composition of Examples 1 and 2 was coated on a copper foil, followed semi-hardening at 100° C., and then heat-pressed at 230° C. for 4 hours by using a vacuum press at a pressure of 3-5 MPa for 4 hours, to thereby manufacture a hardened insulating film. A sample of the insulating film had a size of 4 mm×16 mm, which was then measured.

Evaluation on Thermal Property

The coefficient of thermal expansion (CTE) of each sample of the insulating films manufactured according to the examples and comparative example was measured by using a thermomechanical analyzer (TMA). The glass transition temperature (Tg) was measured by differential scanning calorimetry (DSC) while the temperature of a heat analyzer (TMA 2940, TA Instruments) is raised to 270° C. (first cycle) and 300° C. (second cycle) at a temperature rising rate of 10° C./min, and the results were tabulated in Table 1 below.

TABLE 1

| | | | Comparative |
|---|---|---|---|
| | Example 1 | Example 2 | Example 1 |
| Glass transition temperature (° C.) | 216 | 206 | 200 |
| Coefficient of thermal expansion | 48.1 | 54 | 54.8 |
| α1 < Tg (ppm/° C.) | | | |
| Coefficient of thermal expansion | 135 | 140 | 157 |
| α2 > Tg (ppm/° C.) | | | |

It can be seen from Table 1 above that each of the insulating films according to examples 1 and 2 using naphthalene structured epoxy had a lower coefficient of thermal expansion (CTE) and a higher glass transition temperature (Tg) as compared with the Comparative Example using N,N,N′,N′-tetraglycidyl-4,4′-methylenebisbenzenamine.

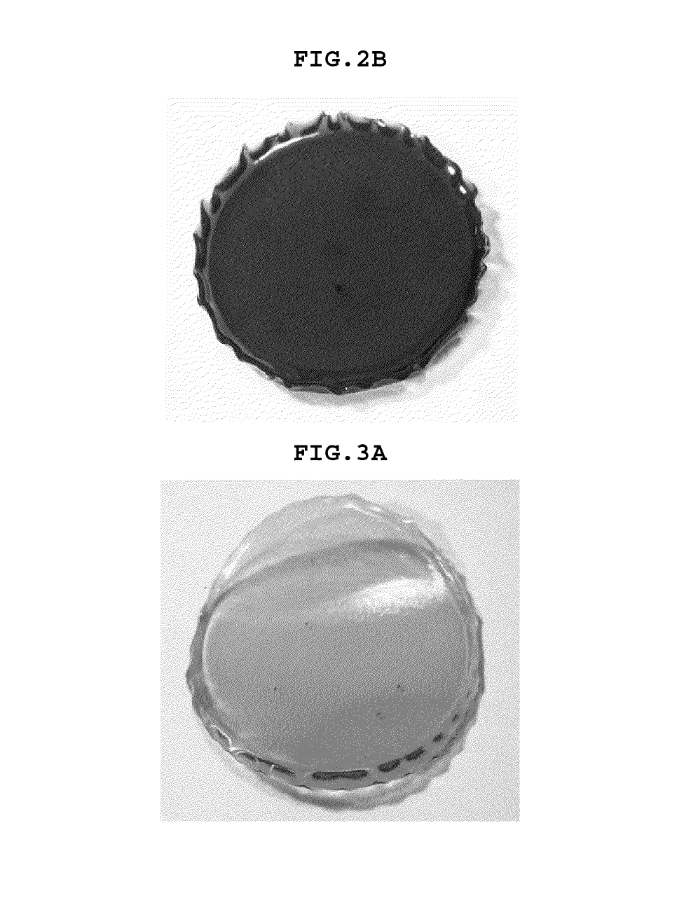

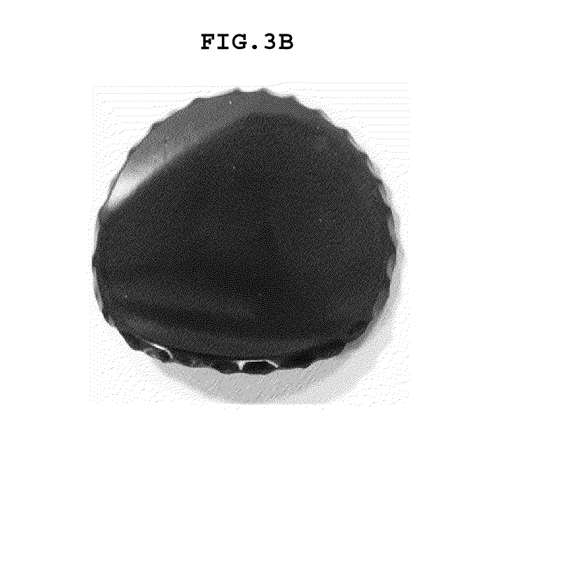

The acid resistance of the insulating film was determined by treating the film manufactured according to each of the examples and comparative example with 50 wt % of a nitric acid solution at mom temperature for 1 hour, followed by washing with distilled water and drying, and then evaluating discoloration or non-discoloration before and after acid treatment. This discoloration or non-coloration can be confirmed from FIGS. 2A to 3B.

As set forth above, the epoxy resin composition for a printed circuit board according to the present invention and the insulating film manufactured therefrom each can have a low coefficient of thermal expansion, excellent heat resistance and chemical resistance, and an increased glass transition temperature.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An epoxy resin composition, comprising:
a liquid crystal oligomer (A) represented by Chemical Formula 1 below;
an epoxy resin (B) represented by Chemical Formula 2 below; and
a hardener (C). 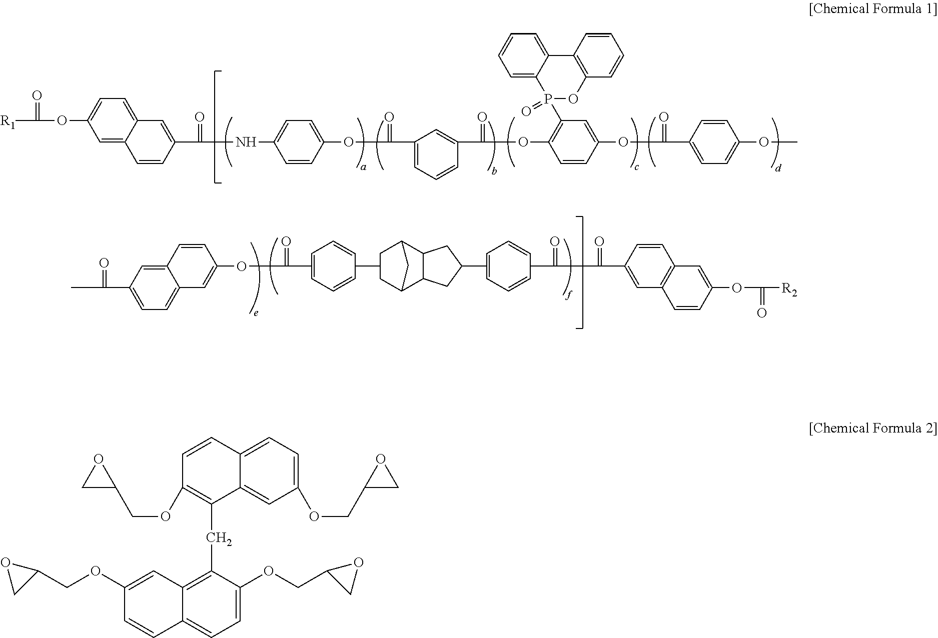
(In Chemical Formula 1, a is an integer of 13 to 26; b is an integer of 13 to 26; c is an integer of 9 to 21; d is an integer of 10 to 30; e is an integer of 10 to 30; and f is an integer of 13 to 17; and R₁ and R₂ are identical or different and each are independently C1˜C20 alkyl)

2. An epoxy resin composition, comprising:
a liquid crystal oligomer (A) represented by Chemical Formula 1 below;
an epoxy resin (B) represented by Chemical Formula 2 below;
a hardener (C); and
an inorganic filler (D). 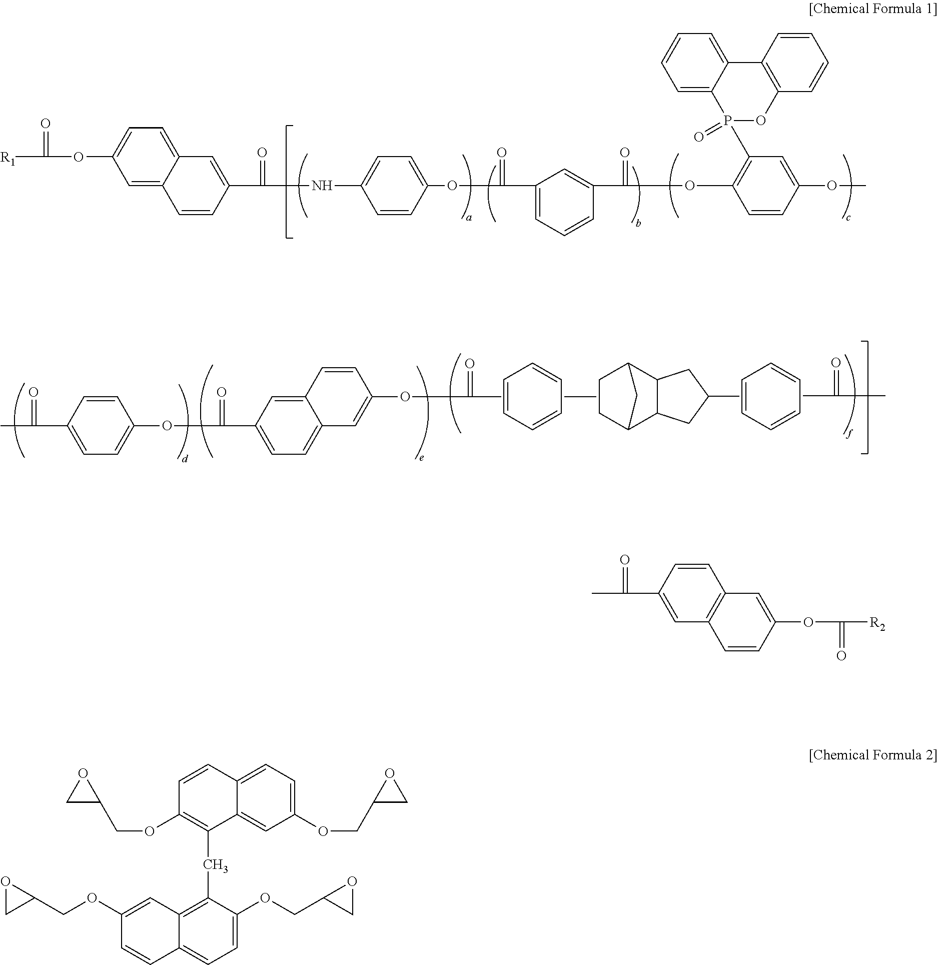
(In Chemical Formula 1, a is an integer of 13 to 26; b is an integer of 13 to 26; c is an integer of 9 to 21; d is an integer of 10 to 30; e is an integer of 10 to 30; and f is an integer of 13 to 17; and R₁ and R₂ are identical or different and each are independently C1˜C20 alkyl)

3. The epoxy resin composition as set forth in claim 1, wherein it includes 35 to 65 wt % of the liquid crystal oligomer (A), 35 to 65 wt % of the epoxy resin (B), and 0.1 to 1 part by weight of the hardener (C) based on 100 parts by weight of the liquid crystal oligomer (A) and the epoxy resin (B).

4. The epoxy resin composition as set forth in claim 2, wherein it includes 35 to 65 wt % of the liquid crystal oligomer (A), 35 to 65 wt % of the epoxy resin (B), 0.1 to 1 part by weight of the hardener (C) based on 100 parts by weight of the liquid crystal oligomer (A) and the epoxy resin (B), and 100 to 160 parts by weight of the inorganic filler (D) based on 100 parts by weight of the liquid crystal oligomer (A) and the epoxy resin (B).

5. The epoxy resin composition as set forth in claim 1, wherein the liquid crystal oligomer (A) has a number average molecular weight of 2,500 to 6,500.

6. The epoxy resin composition as set forth in claim 2, wherein the liquid crystal oligomer (A) has a number average molecular weight of 2,500 to 6,500.

7. The epoxy resin composition as set forth in claim 1, further comprising another epoxy resin, the epoxy resin being at least one selected from a naphthalene based epoxy resin, a bisphenol A epoxy resin, a phenol novolac epoxy resin, a cresole novolac epoxy resin, a rubber modified epoxy resin, and a phosphorous-based epoxy resin.

8. The epoxy resin composition as set forth in claim 2, further comprising another epoxy resin, the epoxy resin being at least one selected from a naphthalene based epoxy resin, a bisphenol A epoxy resin, a phenol novolac epoxy resin, a cresole novolac epoxy resin, a rubber modified epoxy resin, and a phosphorous-based epoxy resin.

9. The epoxy resin composition as set forth in claim 1, wherein the hardener (C) is at least one selected from an amide based hardener, a polyamine based hardener, an acid anhydride hardener, a phenol novolac hardener, a polymercaptan hardener, a tertiary amine hardener, and an imidazole hardener.

10. The epoxy resin composition as set forth in claim 2, wherein the hardener (C) is at least one selected from an amide based hardener, a polyamine based hardener, an acid anhydride hardener, a phenol novolac hardener, a polymercaptan hardener, a tertiary amine hardener, and an imidazole hardener.

11. The epoxy resin composition as set forth in claim 2, wherein the inorganic filler (D) is at least one selected from the group consisting of silica, alumina, barium sulfate, talc, mud, a mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titan oxide, barium zirconate, and calcium zirconate.

12. The epoxy resin composition as set forth in claim 1, further comprising a hardening accelerant (E), the hardening accelerant (E) being at least one selected from 2-methyl imidazole, 2-undecyl imidazol, 2-heptadecyl imidazole, 1,2-dimethyl imidazole, 2-ethyl-4-methyl imidazole, 1,2-dimethyl imidazole, 2-ethyl-4-methyl imidazole, 2-phenyl imidazole, 2-phenyl-4-methyl imidazole, 1-benzyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undencyl imidazolium trimellitate, 1-cyanoethyl-2-phenyl imidazolium trimellitate, 2,4-diamino-6-[2′-methyl imidazolyl-(1′)]ethyl-s-triazine, 2,4-diamino-6-[2′-undecyl imidazolyl-(1′)]-ethyl-s-triazine, 2,4-diamin-6-[2′-ethyl-4′-methyl imidazolyl-(1′)]-ethyl-s-triazine, 2,4-diamino-6-[2′-methyl imidazolyl-(1′)]ethyl-s-triazine isocyanuric acid adduct, 2-phenyl imidazole isocyanuric acid adduct, 2-phenyl-4,5-dihydroxymethyl imidazole, 2-phenyl-4-methyl-5-hydroxy methyl imidazole, 2,3-dihydroxy-1H-pyrrolo[1,2-a]benz imidazole, 1-dodecyl-2-methyl-3-benzyl imidazolium chloride, and 2-methyl imidazolin, 2-phenyl imidazolin.

13. The epoxy resin composition as set forth in claim 2, further comprising a hardening accelerant (E), the hardening accelerant (E) being at least one selected from 2-methyl imidazole, 2-undecyl imidazol, 2-heptadecyl imidazole, 1,2-dimethyl imidazole, 2-ethyl-4-methyl imidazole, 1,2-dimethyl imidazole, 2-ethyl-4-methyl imidazole, 2-phenyl imidazole, 2-phenyl-4-methyl imidazole, 1-benzyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undencyl imidazolium trimellitate, 1-cyanoethyl-2-phenyl imidazolium trimellitate, 2,4-diamino-6-[2′-methyl imidazolyl-(1′)]ethyl-s-triazine, 2,4-diamino-6-[2′-undecyl imidazolyl-(1′)]-ethyl-s-triazine, 2,4-diamin-6-[2′-ethyl-4′-methyl imidazolyl-(1′)]-ethyl-s-triazine, 2,4-diamino-6-[2′-methyl imidazolyl-(1′)]ethyl-s-triazine isocyanuric acid adduct, 2-phenyl imidazole isocyanuric acid adduct, 2-phenyl-4,5-dihydroxymethyl imidazole, 2-phenyl-4-methyl-5-hydroxy methyl imidazole, 2,3-dihydroxy-1H-pyrrolo[1,2-a]benz imidazole, 1-dodecyl-2-methyl-3-benzyl imidazolium chloride, and 2-methyl imidazolin, 2-phenyl imidazolin.

14. The epoxy resin composition as set forth in claim 1, further comprising a thermoplastic resin (F), the thermoplastic resin being at least one selected from a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, and a polyester resin.

15. The epoxy resin composition as set forth in claim 2, further comprising a thermoplastic resin (F), the thermoplastic resin being at least one selected from a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, and a polyester resin.

16. An insulating film manufactured from the epoxy resin composition as set forth in claim 1.

17. A prepreg manufactured by impregnating a substrate with the epoxy resin composition as set forth in claim 1.

18. A multilayer printed circuit board comprising the insulting film as set forth in claim 16.

19. A multilayer printed circuit board comprising the prepreg as set forth in claim 17.
